(19) United States
(12) Patent Application Publication
(10) Pub. No.: US 2023/0376664 A1
(43) Pub. Date: Nov. 23, 2023

(54) EFFICIENT HARDWARE ACCELERATOR ARCHITECTURE EXPLORATION

(71) Applicant: GOOGLE LLC, Mountain View, CA (US)

(72) Inventors: Amir YAZDANBAKHSH, Mountain View, CA (US); Christof ANGERMUELLER, Mountain View, CA (US); Berkin AKIN, Mountain View, CA (US); Yanqi ZHOU, Mountain View, CA (US); James LAUDON, Mountain View, CA (US); Ravi NARAYANASWAMI, Mountain View, CA (US)

(21) Appl. No.: 18/031,073

(22) PCT Filed: Oct. 11, 2021
(86) PCT No.: PCT/US2021/054359

§ 371 Date: Apr. 10, 2023

Related U.S. Application Data
(60) Provisional application No. 63/090,087, filed on Oct. 9, 2020.

(51) Int. Cl. G06F 30/337; G06F 30/331; G06N 3/063

(52) U.S. Cl. CPC G06F 30/337; G06F 30/331; G06N 3/063

(57) ABSTRACT

Methods, systems, and apparatus, including computer programs encoded on computer storage media, for determining architectures of hardware accelerators. In one aspect, a method includes receiving data specifying a plurality of hardware parameters; receiving data specifying one or more predetermined values for each of one or more of the plurality of hardware parameters; generating a plurality of candidate hardware architectures that are specific to a particular machine learning task by repeatedly performing the following operations: selecting a respective value for each of the plurality of hardware parameters; determining a candidate hardware architecture; determining whether the candidate hardware architecture satisfies pre-evaluation criteria; and in response to a positive determination, evaluating a performance measure of the candidate hardware architecture on the particular machine learning task; and generating a final hardware architecture based on the plurality of candidate hardware architectures and on the performance measures.

### CROSS-REFERENCE TO RELATED APPLICATIONS

This application claims priority to U.S. Provisional Application No. 63/090,087, filed on Oct. 9, 2020. The disclosure of the prior application is considered part of and is incorporated by reference in the disclosure of this application.

### BACKGROUND

This specification relates to determining architectures for hardware accelerators.

Hardware accelerators are computing devices having specialized hardware configured to perform specialized computations, e.g., graphics processing units (“GPUs”), field-programmable gate arrays (“FGPAs”), and application-specific integrated circuits (“ASICs”), including tensor processing units (“TPUs”).

### SUMMARY

This specification describes a system implemented as computer programs on one or more computers in one or more locations that determines hardware architectures for target computing devices on which one or more neural networks can be deployed to perform one or more machine learning tasks. More specifically, the system determines an architecture for a hardware accelerator that is part of a target computing device that includes one or more hardware accelerators and that supports performance of the machine learning task with approximately a specified target latency while satisfying hardware design constraints, e.g., in terms of area budget or power consumption.

Hardware accelerators are computing devices that include specialized hardware for performing certain types of operations, e.g., matrix multiplication, more efficiently over non-specialized—or “general purpose”—computing devices. Different hardware accelerators can have different hardware characteristics, e.g., different compute, memory, bandwidth, etc.

As one example, the target computing device that includes one or more hardware accelerators can be a single, specific edge device, e.g., a mobile phone, a smart speaker or another embedded computing device, or other edge device. As a particular example, the edge device can be a mobile phone or other device with a specific type of hardware accelerator or other computer chip on which the neural network will be deployed.

As another example, the target computing device that includes one or more hardware accelerators can be a set of multiple hardware accelerator devices, e.g., ASICs, FPGAs, or tensor processing units (TPUs) on a real-world agent, e.g., a vehicle, e.g., a self-driving car, or a robot.

As yet another example, the target computing device that includes one or more hardware accelerators can be a set of hardware accelerators in a data center.

In general, one innovative aspect of the subject matter described in this specification can be embodied in a method comprising: receiving data specifying a plurality of hardware parameters each associated with one or more values; receiving data specifying one or more predetermined values for each of one or more of the plurality of hardware parameters; generating a plurality of candidate hardware architectures that are specific to a particular machine learning task by repeatedly performing the following operations: selecting, based on (i) a hardware design policy and (ii) the one or more predetermined parameter values for each of one or more of the plurality of hardware parameters, a respective value for each of the plurality of hardware parameters; determining, from the selected values for the plurality of hardware parameters, a candidate hardware architecture; determining whether the candidate hardware architecture satisfies pre-evaluation criteria, including (i) determining a feasibility of the candidate hardware architecture and (ii) determining an estimated performance measure of the candidate hardware architecture on the particular machine learning task; and in response to a positive determination, evaluating, using one or more hardware performance simulators, a performance measure of the candidate hardware architecture on the particular machine learning task; and generating a final hardware architecture based on the plurality of candidate hardware architectures and on the performance measures.

The hardware design policy may comprise a random policy which performs sampling from the plurality of hardware parameters each associated with one or more values with uniform randomness. The hardware design policy may comprise a Bayesian optimization policy. The hardware design policy may comprise a regularized evolutionary search policy. The hardware design policy may comprise a model-based optimization policy. The hardware design policy may comprise a population-based black-box optimization policy.

The following operations may further comprise: updating the hardware design policy based on the performance measure of the candidate hardware architecture on the particular machine learning task.

The method may further comprise: in response to a negative determination, bypassing using the one or more hardware performance simulators to evaluate the performance measure of the candidate hardware architecture on the particular machine learning task.

The method may further comprise updating the hardware design policy based on the negative determination.

The method may further comprise removing the candidate hardware architecture from the plurality of candidate hardware architectures based on which the final hardware architecture is to be generated.

The particular machine learning task may comprise one or more of an image classification, object detection, semantic segmentation, speech recognition, or optical character recognition task.

The performance measure of the candidate hardware architecture on the particular machine learning task may comprise one or more of, for a hardware accelerator having the candidate hardware architecture: a runtime latency of a neural network configured to perform the particular machine learning task deployed on the hardware accelerator, an area of the hardware accelerator, or a power consumption of the hardware accelerator.

Determining the feasibility of the candidate hardware architecture may comprise determining whether the selected values of the plurality of hardware parameters satisfy one or more hardware design constraints.

Determining the estimated performance measure of the candidate hardware architecture on the particular machine learning task may comprise comparing the selected values for the plurality of hardware parameters of the candidate hardware architecture with respective values of the plurality of hardware parameters of other candidate hardware architectures the performance measures of which have already been evaluated using the one or more hardware performance simulators.

The one or more hardware performance simulators may comprise a cycle-accurate simulator or an analytical model.

The one or more predetermined values for each of one or more of the plurality of hardware parameters may be associated with one or more predetermined hardware architectures for different hardware accelerators.

The plurality of hardware parameters may include: one or more compute parameters; one or more memory parameters, and/or one or more bandwidth parameters.

The hardware parameters may define the number of processing elements along a first a dimension of a hardware accelerator and/or along a second, orthogonal, direction of the hardware accelerator.

Receiving data specifying the one or more predetermined values for each of one or more of the plurality of hardware parameters may comprises: receiving data specifying a known hardware design policy; and implementing and using the known hardware design policy to determine the one or more predetermined values for each of one or more of the plurality of hardware parameters.

Another innovative aspect of the subject matter described in this specification can be embodied in a machine learning task-specific hardware accelerator having an architecture defined by performing a process comprising the respective operations of any one of the preceding claims.

Other embodiments of this aspect include corresponding computer systems, apparatus, and computer programs recorded on one or more computer storage devices, each configured to perform the actions of the methods. A system of one or more computers can be configured to perform particular operations or actions by virtue of software, firmware, hardware, or any combination thereof installed on the system that in operation may cause the system to perform the actions. One or more computer programs can be configured to perform particular operations or actions by virtue of including instructions that, when executed by data processing apparatus, cause the apparatus to perform the actions.

The subject matter described in this specification can be implemented in particular embodiments so as to realize one or more of the following advantages.

Hardware accelerators are specialized hardware configured to perform specialized computations and are generally more computationally efficient than their general purpose counterparts, but are also generally associated with higher operational costs because of the energy required to power and maintain the accelerators. Effectively performing machine learning tasks, e.g., vision tasks, natural language processing tasks, or other tasks that require near-real-time responses to be provided to users, using neural networks deployed on the hardware accelerators requires specifically designed hardware accelerator architectures, i.e., architectures that have been customized for the machine learning task, the neural network, or both.

Existing approaches for accelerator architecture design generally involves exploring through a large, multimodal candidate architecture space to determine respective values for hardware parameters, and thereafter evaluating a performance of a hardware accelerator the architecture of which has been defined by the determined parameter values. For most modern hardware accelerators, e.g., graphics processing units (GPUs) or tensor processing units (TPUs), this requires selecting a set of parameter values from a large discrete design space, an integer design space, an ordinal design space, a cardinal design space, or a combination thereof. Repeatedly performing this search process is computationally intensive and consumes a significant amount of computational resources, both because of the exhaustive nature of the parameter value sampling step and the cost to run expensive simulators or other analytical models for hardware performance evaluation.

The described techniques, on the other hand, can perform the hardware accelerator architecture designing process by allowing usage of prior knowledge gained through related design tasks, e.g., designing hardware accelerators for different machine learning tasks, different network architectures, or under different design constraints, e.g., in terms of area, power consumption, or latency, while additionally using a pre-evaluation filtering technique which bypasses evaluation for presumably inferior or infeasible hardware architectures. The described techniques reduce the amount of computational resources consumed by hardware performance evaluation process because costly evaluation for all architectures defined by sampled parameter values is no longer required. Instead, only a relatively small number of architectures that have been determined both to be feasible and to match or even exceed the performance of already evaluated hardware architectures need to be evaluated.

The described techniques can therefore be used to search for architectures for hardware accelerators that can support performance of any of a variety of machine learning tasks while satisfying area, resource consumption, or other design constraints and to therefore identify a single architecture or a range of architectures on which neural networks can be deployed to effectively compute inferences with a target latency. Moreover, the described techniques allow a system to identify a hardware architecture that satisfies various design constraints while consuming many fewer computational resources than existing techniques for searching for such architectures.

The details of one or more implementations of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example hardware architecture search system.

FIG. 2 is a flow diagram of an example process for determining a final hardware architecture for a hardware accelerator.

FIG. 3 is a flow diagram of an example process for generating and evaluating a candidate hardware architecture.

Like reference numbers and designations in the various drawings indicate like elements.

### DETAILED DESCRIPTION

This specification describes a system implemented as computer programs on one or more computers in one or more locations that can determine an architecture for a hardware accelerator that is part of a target computing device that includes one or more hardware accelerators and that supports performance of a particular machine learning task with approximately a specified target latency while satisfying hardware design constraints, e.g., in terms of area budget or power consumption.

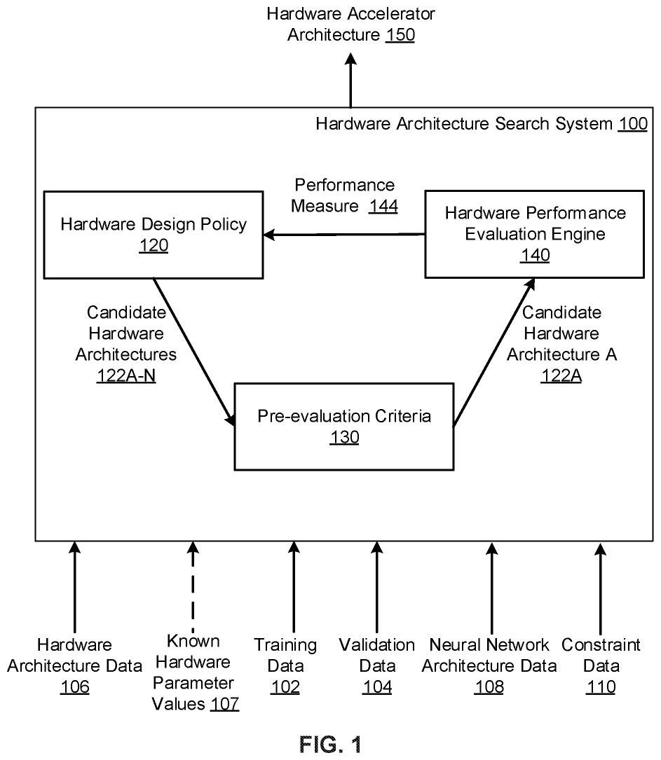

FIG. 1 shows an example hardware architecture search system 100. The neural architecture and hardware architecture search system 100 is an example of a system implemented as computer programs on one or more computers in one or more locations, in which the systems, components, and techniques described below can be implemented.

The hardware architecture search system 100 is a system that obtains hardware architecture data 106 that describes a space of candidate hardware accelerator architectures and that searches through the space of candidate hardware accelerator architectures to determine a final hardware architecture 150 for a hardware accelerator on which a neural network will be deployed to perform the particular machine learning task.

Depending on the task, the neural network to be deployed on the hardware accelerator can be configured to receive any kind of digital data input and to generate any kind of score, classification, or regression output based on the input.

In some cases, the neural network is configured to perform an image processing task, i.e., receive an input image and to process the input image to generate a network output for the input image. In this specification, processing an input image refers to processing the intensity values of the pixels of the image using a neural network. For example, the task may be image classification and the output generated by the neural network for a given image may be scores for each of a set of object categories, with each score representing an estimated likelihood that the image contains an image of an object belonging to the category. As another example, the task can be image embedding generation and the output generated by the neural network can be a numeric embedding of the input image. As another example, the task can be object detection and the output generated by the neural network can identify locations in the input image at which particular types of objects are depicted. As yet another example, the task can be image segmentation and the output generated by the neural network can define for each pixel of the input image which of multiple categories the pixel belongs to.

As another example, if the inputs to the neural network are Internet resources (e.g., web pages), documents, or portions of documents or features extracted from Internet resources, documents, or portions of documents, the task can be to classify the resource or document, i.e., the output generated by the neural network for a given Internet resource, document, or portion of a document may be a score for each of a set of topics, with each score representing an estimated likelihood that the Internet resource, document, or document portion is about the topic.

As another example, if the inputs to the neural network are features of an impression context for a particular advertisement, the output generated by the neural network may be a score that represents an estimated likelihood that the particular advertisement will be clicked on.

As another example, if the inputs to the neural network are features of a personalized recommendation for a user, e.g., features characterizing the context for the recommendation, e.g., features characterizing previous actions taken by the user, the output generated by the neural network may be a score for each of a set of content items, with each score representing an estimated likelihood that the user will respond favorably to being recommended the content item.

As another example, if the input to the neural network is a sequence of text in one language, the output generated by the neural network may be a score for each of a set of pieces of text in another language, with each score representing an estimated likelihood that the piece of text in the other language is a proper translation of the input text into the other language.

As another example, if the input to the neural network is a sequence representing a spoken utterance, the output generated by the neural network may be a score for each of a set of pieces of text, each score representing an estimated likelihood that the piece of text is the correct transcript for the utterance.

As another example, the task may be an audio processing task. For example, if the input to the neural network is a sequence representing a spoken utterance, the output generated by the neural network may be a score for each of a set of pieces of text, each score representing an estimated likelihood that the piece of text is the correct transcript for the utterance.

As another example, the task may be a keyword spotting task where, if the input to the neural network is a sequence representing a spoken utterance, the output generated by the neural network can indicate whether a particular word or phrase (“hotword”) was spoken in the utterance. As another example, if the input to the neural network is a sequence representing a spoken utterance, the output generated by the neural network can identify the natural language in which the utterance was spoken.

As another example, the task can be a natural language processing or understanding task, e.g., an entailment task, a paraphrase task, a textual similarity task, a sentiment task, a sentence completion task, a grammaticality task, and so on, that operates on a sequence of text in some natural language.

As another example, the task can be a text to speech task, where the input is text in a natural language or features of text in a natural language and the network output is a spectrogram or other data defining audio of the text being spoken in the natural language.

As another example, the task can be a health prediction task, where the input is electronic health record data for a patient and the output is a prediction that is relevant to the future health of the patient, e.g., a predicted treatment that should be prescribed to the patient, the likelihood that an adverse health event will occur to the patient, or a predicted diagnosis for the patient.

As another example, the task can be an agent control task, where the input is an observation characterizing the state of an environment and the output defines an action to be performed by the agent in response to the observation. The agent can be, e.g., a real-world or simulated robot, a control system for an industrial facility, or a control system that controls a different kind of agent.

As another example, the task can be a genomics task, where the input is a sequence representing a fragment of a DNA sequence or other molecule sequence and the output is either an embedding of the fragment for use in a downstream task, e.g., by making use of an unsupervised learning technique on a data set of DNA sequence fragments, or an output for the downstream task. Examples of downstream tasks include promoter site prediction, methylation analysis, predicting functional effects of non-coding variants, and so on.

In some cases, the machine learning task is a combination of multiple individual machine learning tasks, i.e., the neural network is configured to perform multiple different individual machine learning tasks, e.g., two or more of the machine learning tasks mentioned above. For example, the neural network can be configured to perform multiple individual natural language understanding tasks. Optionally, the network input can include an identifier for the individual natural language understanding task to be performed on the network input. As another example, the neural network can be configured to perform multiple individual image processing or computer vision tasks, i.e., by generating the output for the multiple different individual image processing tasks in parallel by processing a single input image.

In general, the space of candidate hardware accelerator architectures can be defined by possible values of a set of searchable hardware parameters. Example hardware parameters can include the number of compute units, the size of local or global memories, the bandwidth, and the like, that are associated with a given hardware accelerator, e.g., an industry-standard, highly parameterized edge accelerator, which collectively specify the hardware architecture including corresponding compute characteristics of the hardware accelerator. Each hardware parameter is typically associated with one or more values, e.g., integer or floating point values, that can be selected from a set of possible values for the hardware parameter. An example parameterized edge accelerator may include a 2D array of processing elements with multiple compute lanes and dedicated register files, each operating in single-instruction multiple-data (SIMD) style with multiply-accumulate (MAC) compute units.

Example hardware (i.e. architecture) parameters may for example comprise compute parameters (e.g. the number of processing elements along at least one dimension of the hardware accelerator), memory parameters (e.g. the size of one or more local or global memories) or bandwidth (e.g. I/O bandwidth) parameters. An example of a hardware accelerator architecture search space and the corresponding set of hardware parameters that define the search space is described below in Table 1, which illustrates microarchitecture parameters and their number of discrete values in the search space.

TABLE 1

| Accelerator | # discrete | Accelerator | # discrete |
|---|---|---|---|
| Parameter | values | Parameter | values |
| # of PEs-X | 10 | # of PEs-Y | 10 |
| Local Memory | 7 | # of SIMD units | 7 |
| Global Memory | 11 | # of Compute lanes | 10 |
| Instruction Memory | 4 | Parameter Memory | 5 |
| Activation Memory | 7 | I/O Bandwidth | 6 |

In this example, “PE” refers to a processing element that is capable of performing matrix multiplications in a single instruction multiple data (SIMD) paradigm with multiply-accumulate (MAC) compute units, e.g., with “# of PEs-X” referring to the number of processing elements along a horizontal dimension of the hardware accelerator. The hardware accelerator also includes distributed local and global (buffer) memories that are shared across the compute lanes and PEs, respectively.

When searching through the space of candidate hardware accelerator architectures to determine the final hardware architecture, the system 100 can perform the search in an exhaustive manner, i.e., search the entire space of possible architectures. In some implementations, however, the system 100 need not attempt to search the entire space by using the techniques described below. In particular, in these implementations, to allow usage of prior knowledge gained through related design tasks, the system 100 can perform the search by beginning from one or more predetermined values 107 for each of one or more of the plurality of hardware parameters. For example, these predetermined values 107 can be known parameter values associated with a given hardware accelerator that has attained at least a threshold level of performance on a relevant machine learning task. As another example, these predetermined values 107 can be known parameter values associated with a given hardware accelerator that has been specifically designed to support the operation of a neural network with a similar architecture. As another example, these predetermined values 107 can be known parameter values associated with a given hardware accelerator that has been designed for a same machine learning task but under different constraints, e.g., tighter area budget, higher power consumption, or lower latency. As yet another example, these predetermined values 107 can be parameter values determined by another hardware design policy, e.g., by a learnt machine learning-based design policy that has been used in a related hardware design task. In other words, in this example, at the beginning of the search, the system 100 can use an already implemented, e.g., already trained, hardware design policy 120, to determine the one or more predetermined values 107 for each of one or more of the plurality of hardware parameters.

The system 100 also obtains neural network architecture data 108 that specifies a configuration or architecture of the neural network which, once the final hardware accelerator architecture 150 is determined, is to be deployed on a hardware accelerator having the determined final hardware accelerator architecture 150 so as to perform the particular machine learning task.

In some cases, instead of or in addition to specifying a single neural network architecture, the neural network architecture data 108 may describe an entire space of candidate neural network architectures, from which the final architecture of the neural network can be jointly determined by the system 100, i.e., as part of the hardware accelerator architecture search process. In some of these cases, the space of candidate neural network architectures can be initialized or derived from one or more known neural network architectures. MobileNet, including its derivative, MobileNetEdge, and EfficientNet, described in more detail at Howard, Andrew G., et al. “Mobilenets: Efficient convolutional neural networks for mobile vision applications.” arXiv preprint arXiv:1704.04861 (2017), Gupta, Suyog and Akin, Berkin. “Accelerator-aware neural network design using automl.” arXiv preprint arXiv:2003.02838, (2020), and Tan, Mingxing, and Quoc V. Le. “Efficientnet: Rethinking model scaling for convolutional neural networks.” arXiv preprint arXiv:1905.11946 (2019), respectively, are examples of such known neural network architectures.

The neural network architecture generally defines the number of layers in the neural network, the operations performed by each of the layers, and the connectivity between the layers in the neural network, i.e., which layers receive inputs from which other layers in the neural network. Thus, the search space of candidate neural network architectures can be defined by possible values of a set of hyperparameters, i.e., can include a set of hyperparameters, each of which may have a predetermined set of possible values. A selected value of a hyperparameter can be set prior to the commencement of the training of the neural network and can impact the operations performed by the neural network. Collectively, the selected values of the hyperparameters can define an architecture for the neural network.

For example, for a convolutional layer, the hyperparameters that define the operations performed by the layer can include the number of filters of the layer, the filter height for each filter, the filter width for each filter, the stride height for applying each filter, and the stride width for each filter. In this example, some of these can be removed, e.g., the values of certain ones of these hyperparameters can be assumed to be fixed, other hyperparameters, e.g., type of activation function, whether or not the convolutions are dilated or masked, and so on, can be added, or both. As another example, for an inverted residual layer, the hyperparameters can include a skip connection hyperparameter that defines which earlier layers have a skip connection to the layer, as well as an expansion ratio hyperparameter. For each inverted residual layer, the expansion ratio refers to the ratio between the number of the output channels and that of the input channels.

In some cases, the neural network architecture data 108 may also include additional information associated with the neural network architecture that can be used by the system 100 during the hardware architecture search process. For example, the neural network architecture data 108 may identify a particular task or a particular domain of tasks (e.g., image classification, object detection, semantic segmentations, optical character recognition, and the like) on which the neural network architecture is specialized. As another example, the data 108 may specify a total size of memory (e.g., in terms of megabytes) required to store all the parameters of a neural network having the architecture. As yet another example, the data 108 may specify a number of multiply-accumulate (MAC) operations required when using the neural network having the architecture to perform one forward pass of inference.

In some cases, the system 100 also obtains training data 102 for training a neural network to perform the particular task and a validation set 104 for evaluating the performance of the neural network on the particular task. Generally, both the training data 102 and the validation data 104 include a set of neural network inputs (also referred to as training or validation examples) and, for each network input, a respective target output that should be generated by the neural network to perform the particular task. The training data 102 and the validation data 104 can include different sets of neural network inputs, i.e., so that the validation data 104 can be used to effectively measure how well a neural network that has been trained on the training data 102 performs on new inputs.

The system can receive the hardware architecture data 106, neural network architecture data 108, training data 102 for training the neural network, or a combination thereof in any of a variety of ways. For example, the system 100 can receive training data as an upload from a remote user of the system over a data communication network, e.g., using an application programming interface (API) made available by the system 100. The system 100 can then randomly divide the received training data into the training data 102 and the validation data 104. As another example, the system 100 can receive an input from a user specifying which data that is already maintained by the system 100 should be used for training the neural network. As yet another similar example, the system 100 can receive an input from a user specifying from where on a network, e.g., from where on Internet, the hardware architecture data 106 or the neural network architecture data 108 can be retrieved.

The system 100 also receives, e.g., from a user, constraint data 110 that specifies one or more hardware design constraints that must be satisfied in the final hardware accelerator architecture 150.

For example, the constraint data 110 can include data specifying a target latency for performing the machine learning task after training and during inference, i.e., for processing new inputs for the particular task by using a particular neural network deployed on the hardware accelerator after the hardware architecture of which has been determined. Generally, the target latency is a target latency for the neural network when deployed on the hardware accelerator. The target latency measures the time, e.g., in milliseconds, required to perform inference for a batch of one or more examples, i.e., to process each example in the batch using the neural network, when the neural network is deployed on the hardware accelerator that has the final hardware accelerator. As another example, the constraint data 110 can include data specifying the target area of the hardware accelerator, e.g., the maximum allowable area of the hardware accelerator measured in square millimeters. As yet another example, the constraint data 110 can include data specifying the target power (or energy) consumption of the hardware accelerator when performing the particular task.

Thus, using the techniques described below, the system 100 can effectively determine a hardware architecture for a hardware accelerator having an area (or power consumption) that is no greater than the target hardware area (or target power consumption) and on which a neural network can be deployed and configured to perform a particular machine learning task with an acceptable accuracy while having an acceptable latency, e.g., a latency that is approximately equal to or no greater than the target latency specified in the constraint data.

The system 100 then uses the training data 102, the validation data 104, the hardware architecture data 106, the neural network architecture data 108, and the constraint data 110 to determine a final hardware accelerator architecture 150 by searching through a space of candidate hardware accelerator architectures.

In general, during the search process, the system 100 repeatedly generates different candidate hardware configurations 122 in accordance with a hardware design policy 120. The hardware design policy 120 is generally implemented as software that is configurable to generate policy outputs including respective values of a set of hardware parameters that collectively define a possible architecture for the hardware accelerator. For example, the software has adjustable settings for generating different values for different hardware parameters. In some cases, the system 100 can implement and use a new hardware design policy 120 for each different hardware accelerator architecture design task. In other cases, the system 100 can use the same policy 120 across multiple design tasks (during which the policy 120 may be fine-tuned but not entirely reconstructed), so as to allow for transfer of knowledge gained between related hardware accelerator architecture design tasks.

The system also makes use of a hardware performance evaluation engine 140 to evaluate the performance measure 144 of the candidate hardware accelerator 122 determined by using the hardware design policy 120 which, when used to update the hardware design policy 120 and to drive the hardware design policy 120 to propose new candidate hardware architectures, can result in the policy to output hardware parameter values that collectively define new hardware architectures that more effectively support the operation of a deployed neural network in performing the task, better satisfies the hardware design constraints specified by the constraint data, or both.

The hardware performance evaluation engine 140 generally implements one or more hardware simulators that simulate an instance of a hardware accelerator having the candidate hardware architecture. One example of such hardware simulator is a cycle-accurate performance simulator. The system 100 can use the cycle-accurate performance simulator to determine an estimated latency, e.g., in milliseconds, of the neural network on performing the particular machine learning task when being deployed on the (simulated) instance of hardware accelerator. Another example of such hardware simulator is an analytical area estimator. The system 100 can use the analytical area estimator to determine an estimated area, e.g., in square millimeters, of the instance of the hardware accelerator.

However, evaluating the performance measures using hardware simulations is extremely time-consuming. In some cases, the hardware simulator can take as long as one hour, or more, merely to evaluate the performance measure of a single hardware accelerator with a proposed hardware architecture. The query to the hardware simulator may thus become the bottleneck of efficient hardware architecture search.

Therefore, for each candidate hardware architecture determined by using the hardware design policy 120, prior to performing the costly hardware simulation, the system 100 first evaluates the candidate hardware architecture against a set of one or more pre-evaluation criteria 130 and, correspondingly, proceeds to use the hardware simulators to evaluate the performance measures only for those candidate hardware architectures that satisfy the pre-evaluation criteria. In other words, the system 100 defines and uses the pre-evaluation criteria 130 to effectively preclude the need for performing hardware simulation to simulate the effect of deploying a neural network on each and all of the candidate hardware architectures generated during the search process. Instead, only a relatively small number of costly hardware simulations need to be run, thereby shortening the design cycle for hardware accelerators.

In some cases, during each search iteration, the system 100 can use the hardware design policy 120 to generate a batch of candidate hardware architectures 122A-N, where N can be any positive integer greater than one, and may end up only using hardware simulation to evaluate the performance measure for a single candidate hardware architecture, e.g., candidate hardware architecture 122A, which is the only candidate architecture that satisfies the pre-evaluation criteria in the entire batch of candidate architectures.

For example, the pre-evaluation criteria 130 include one or more feasibility criteria which rejects any infeasible candidate hardware architectures. The feasibility criteria of a hardware architecture may depend on the target software (source code for a neural network), the underlying hardware, or both. For example, the hardware architecture may be infeasible because it specifies a configuration or design that is unbuildable on silicon. As another example, the hardware architecture may be infeasible because it specifies a hardware on which the target software cannot compile, e.g., due to insufficient number of memory units of the hardware accelerator.

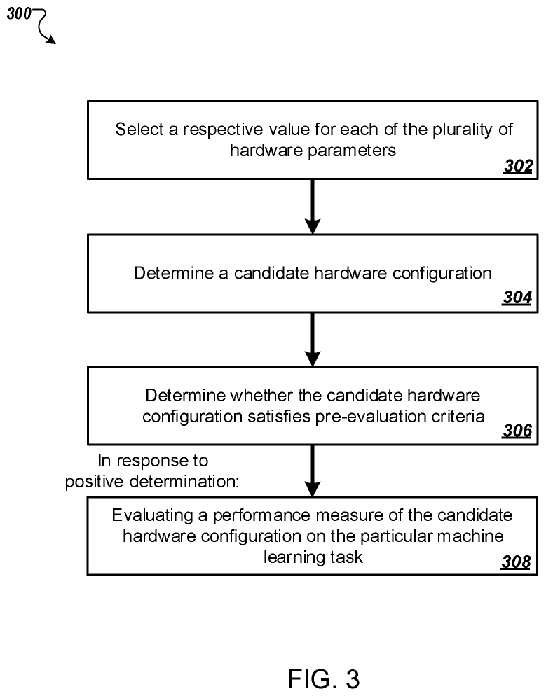

As another example, the pre-evaluation criteria 130 include one or more estimated performance criteria which rejects any candidate hardware architectures that have been preliminarily estimated to fall short of a satisfactory hardware performance on the particular machine learning task, e.g., in terms of the target runtime latency of a neural network configured to perform the particular machine learning task when deployed on the hardware accelerator, the target area of the hardware accelerator, or the target power consumption of the hardware accelerator when performing the task. Using the pre-evaluation criteria during the search, including determining estimated hardware accelerator performance measures will be described in more detail below with reference to FIG. 3.

After the search process has completed, e.g., once a predetermined number of search iterations has been performed or a certain amount of time has elapsed, the hardware architecture search system 100 can select the candidate hardware accelerator architecture that has the best performance measures, best satisfies the various hardware design constraints specified in the constraint data 110, or both as the final architecture 150 of the hardware accelerator. Instead or in addition, the system 100 can generate a new candidate hardware accelerator architecture by using the updated hardware design policy 120, and use the new architecture as the final architecture 150 of the hardware accelerator.

The hardware architecture search system 100 can then generate as output hardware accelerator architecture data that specifies the architecture of the hardware accelerator, e.g., data specifying the layout of the processing elements on the hardware accelerator, the number of compute lanes, the size of the local or global memory, and the bandwidth.

For example, the hardware architecture search system 100 can output the hardware accelerator architecture data to the user that provided the constraint data 110. As another example, the hardware architecture search system 100 can output the hardware accelerator architecture data, e.g., by a wired or wireless network, to a semiconductor fabrication facility that houses semiconductor fabrication equipment that can be used to fabricate the hardware accelerators that have the final hardware architecture.

In some cases, the output data also identifies a network architecture of a neural network that works best (e.g., in terms of accuracy in performing the task) when deployed on the hardware accelerator having the final architecture. In some of these cases, the output data also includes trained values of the parameters of the neural network that had the network architecture that have been determined from the search process.

In some implementations, the system 100 could be included as part of a software tool for designing and/or analyzing integrated circuits, e.g., an electronic design automation (EDA) tool, and the hardware accelerator architecture data may then be provided to another component of the tool for further refinement or evaluation before the hardware accelerator is fabricated.

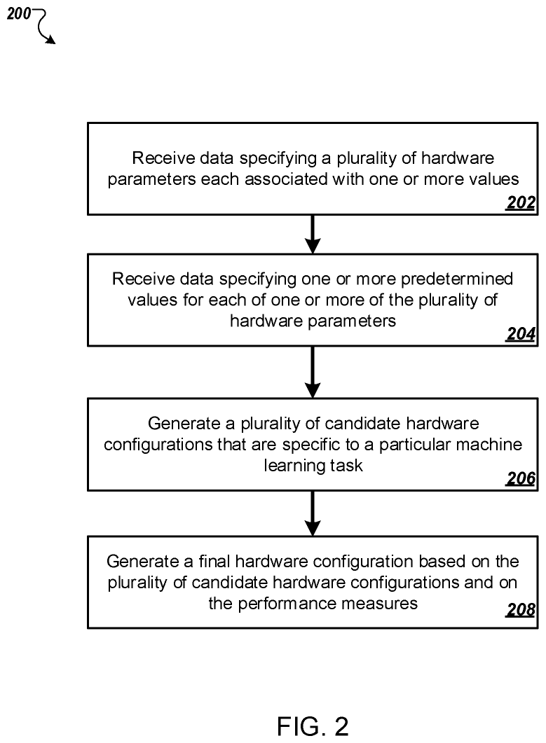

FIG. 2 is a flow diagram of an example process 200 for determining a final hardware configuration for a hardware accelerator. For convenience, the process 200 will be described as being performed by a system of one or more computers located in one or more locations. For example, a neural architecture search system, e.g., the hardware architecture search system 100 of FIG. 1, appropriately programmed, can perform the process 200.

The system receives data specifying a plurality of hardware parameters (step 202). Each hardware parameter can be associated with one or more values, e.g., integer or floating point values, that can be selected from a set of possible values for the hardware parameter. Collectively, the plurality of hardware parameters and the corresponding sets of possible hardware parameter values define the space of candidate hardware accelerator architectures.

The system receives data specifying one or more predetermined values for each of one or more of the plurality of hardware parameters (step 204). As described above, these predetermined values may be defined by (or derived from) known parameter values of any given hardware accelerator that has already been designed and/or manufactured for use within the same domain of application, e.g., for a different but relevant machine learning task, or for the same task but supporting a different neural network model, having different hardware design constrains, or both. Because these known parameter values generally encapsulate prior knowledge gained through the other relevant hardware accelerator design tasks, the system is able to use this additional source of information about the predetermined parameter values to search for better hardware accelerator configurations as well as to achieve improved overall sample-efficiency of the search process.

The system receives, e.g., from a user, constraint data that specifies one or more hardware design constraints that must be satisfied in the final hardware accelerator architecture.

In some cases, the system also receives data that specifies a target neural network architecture or data that describes a space of candidate neural network architectures, including any additional information that characterizes the neural network.

In some cases, the system also receives the training data for training a neural network to perform the particular task and a validation set for evaluating the performance of the neural network on the particular task.

The system generates a plurality of candidate hardware architectures that are specific to a particular machine learning task (step 206). In particular, the system can generate different candidate hardware architectures by using any of a variety of hardware design policies and from (i) the received data that specifies the space of candidate hardware accelerator architectures, (ii) the received data that specifies the predetermined hardware parameter values, (iii) the constraint data and, optionally, (iv) the neural network architecture data and the (v) training and validation data.

For example, the hardware design policy can be a random policy. To generate each candidate hardware configuration, the system can randomly sample respective parameter values for the plurality of hardware parameters from the space of candidate hardware accelerator architectures. That is, the system can determine, from the respective set of possible values associated with each of the plurality of hardware parameters, a selected value for each hardware parameter based on performing sampling with uniform randomness.

As another example, the hardware design policy can be a regularized evolutionary search policy. During the search process, the system can maintain a population of candidate hardware accelerator architectures. At each search iteration, new architectures are generated by selecting one or more parent architectures from the population using tournament selection techniques, and then generating a new child architecture from the one or more parent architectures. Specifically, when there is a single parent architecture, the child architecture may be generated by mutating one or more of the hardware parameters of the parent architecture. And when there are two or more parent architectures, the child architecture may be generated by crossing over and optionally mutating. Existing candidate hardware accelerator architectures may be removed from the population after every fixed number of search iterations to encourage exploration. Regularized evolutionary search policy is described in more details at Esteban Real, Alok Aggarwal, Yanping Huang, and Quoc V Le. Regularized evolution for image classifier architecture search. In Proceedings of the aaai conference on artificial intelligence, volume 33, pp. 4780-4789, 2019.

As another example, the hardware design policy can be a model-based optimization policy. At each search iteration, a set of candidate regression models are trained on the data acquired so far and their hyperparameter values are optimized by randomized search and cross-validation. Models with a cross-validation score above a certain threshold are ensembled to define an acquisition function, which defines various heuristics employed to evaluate the usefulness of one of more design points (candidate hardware accelerator architectures) for achieving the objective of optimizing (e.g., maximizing) an underlying black box optimization function. The acquisition function is optimized by evolutionary search and the proposed candidate accelerator architectures with the highest acquisition function values are used for the objective function evaluation in the next iteration. Model-based optimization policy is described in more details at Christof Angermueller, David Dohan, David Belanger, Ramya Deshpande, Kevin Murphy, and Lucy Colwell. Model-based reinforcement learning for biological sequence design. In International Conference on Learning Representations, 2019.

As another example, the hardware design policy can be a Bayesian optimization policy. As an alternative approach to the model-based optimization policy, the Bayesian optimization policy in this example uses a Gaussian process regressor and expected improvement acquisition function, which is optimized by gradient-free hill-climbing techniques. Bayesian optimization policy is described in more details at Daniel Golovin, Benjamin Solnik, Subhodeep Moitra, Greg Kochanski, John Karro, and D Sculley. Google vizier: A service for black-box optimization. In Proceedings of the 23rd ACM SIGKDD international conference on knowledge discovery and data mining, pp. 1487-1495, 2017.

As yet another example, the hardware design policy can be a population-based black-box optimization policy, a technique for batched black box optimization that uses an ensemble of multiple optimization algorithms to propose the candidate hardware accelerator architectures at each iteration of the search process. During the search process, acquired data can be exchanged between optimization algorithms in the ensemble, and optimizers are weighted by their past performance to generate new candidate hardware accelerator architectures. In some cases, the hyperparameters of optimizers may also be updated using evolutionary search. Population-based black-box optimization policy is described in more details at Christof Angermueller, David Belanger, Andreea Gane, Zelda Mariet, David Dohan, Kevin Murphy, Lucy Colwell, and D Sculley. Population-based black-box optimization for biological sequence design. arXiv preprint arXiv:2006.03227, 2020.

By making use of the hardware design policy in any of the above examples, the system repeatedly, i.e., at each of multiple iterations of the search process, generates different batches of candidate hardware accelerator architectures and, for each batch of candidate architectures, uses hardware simulation to determine a respective performance measure of every selected candidate architecture that satisfies the pre-evaluation criteria. As described above, the system uses the pre-evaluation criteria to reduce the total number of costly hardware simulations and to improve the overall sample-efficiency of the search process. This technique is described in more detail below with reference to FIG. 3.

In some implementations, at the end of each search iteration, the system updates the hardware design policy based on the determined performance measures of the selected candidate hardware configurations so as to encourage it to propose better candidate hardware accelerator architectures in the next iteration. In some implementations where the system jointly searches for neural network architectures, the system also updates a controller policy based on the determined performance measures so as to encourage it to propose better candidate neural network architectures in the next iteration.

After the search process has completed, e.g., once a predetermined number of search iterations has been performed or a certain amount of time has elapsed, the system generates a final hardware architecture based on the plurality of candidate hardware architectures and on the performance measures (step 208). For example, the system can select the candidate hardware accelerator architecture that has the best performance measures, best satisfies the various hardware design constraints specified in the constraint data, or both as the final architecture of the hardware accelerator. Instead or in addition, the system can generate a new candidate hardware accelerator architecture by using the updated hardware design policy, and use the new architecture as the final architecture of the hardware accelerator.

FIG. 3 is a flow diagram of an example process 300 for generating and evaluating a candidate hardware architecture. For convenience, the process 300 will be described as being performed by a system of one or more computers located in one or more locations. For example, a neural architecture search system, e.g., the hardware architecture search system 100 of FIG. 1, appropriately programmed, can perform the process 300.

The system can repeatedly perform the process 300 for each candidate hardware architecture at each iteration of the search process.

The system selects, based on (i) the hardware design policy and (ii) the one or more predetermined parameter values for each of one or more of the plurality of hardware parameters, a respective value for each of the plurality of hardware parameters (step 302). Collectively, the selected values for the plurality of hardware parameters define a candidate architecture of the hardware accelerator. For example, the hardware design policy can be one of: a random policy, a Bayesian optimization policy, a regularized evolutionary search policy, a model-based optimization policy, or a population-based black-box optimization policy.

In particular, instead of running the hardware design policy to determine new candidate hardware accelerator architectures from scratch, i.e., beginning the search process by proposing arbitrary values for the hardware parameters, the system makes use of the one or more predetermined parameter values that have been determined (and validated) as a result of some other relevant hardware accelerator design tasks. This “head start” phase of the search process can guide the hardware design policy to more effectively propose new candidate architectures starting from the very early iterations.

For example, when searching for a hardware accelerator on which a target neural network is to be deployed to perform the particular machine learning task, the system can begin the search process from known memory parameter values of another hardware accelerator on which a neural network with a comparable memory footprint to the target neural network could have been deployed. In this example, some of the hardware parameters, e.g., hardware parameters that relate to onboard memory, can be assumed to be (relative) fixed, while the respective values of other parameters, e.g., hardware parameters that define the number and the layout of processing elements or compute lanes, can be more extensively explored. As another example, the system can begin the search process from parameter values determined by using another known hardware design policy that was previously used for designing a different hardware accelerator design task.

The system determines, from the selected values for the plurality of hardware parameters, a candidate hardware configuration (step 304).

The system determines whether the candidate hardware configuration satisfies pre-evaluation criteria (step 306), including (i) determining a feasibility of the candidate hardware configuration and (ii) determining an estimated performance measure of the candidate hardware configuration on the particular machine learning task.

More specifically, the pre-evaluation criteria can include one or more feasibility criteria which rejects any infeasible candidate hardware architectures. The feasibility criteria of a hardware architecture may depend on the one or more hardware design constraints specified in the constraint data. For example, the hardware architecture may be infeasible because it specifies a placement of greater than a threshold number of process elements (PEs) along one or both dimensions of the hardware accelerator that would result in the hardware accelerator to have an area that exceeds the target area as specified in the constraint data. The feasibility criteria of a hardware architecture may additionally depend on the target software (source code for a neural network), the underlying hardware, or both. For example, the system can maintain data that includes a list of configurations or designs that are known to be unbuildable on silicon and, in the cases where the candidate hardware accelerator architecture specifies any one of such unbuildable configurations, determine that candidate architecture may be infeasible. As yet another example, the hardware architecture may be infeasible because it specifies a hardware on which the target software cannot compile, e.g., due to insufficient number of memory units of the hardware accelerator.

Thus, the system can determine the feasibility of the candidate hardware configuration based on determining whether the selected values of the plurality of hardware parameters satisfy the one or more hardware design constraints and, in some cases, the prerequisites for building a hardware accelerator having the candidate architecture as well as the inherent hardware requirements for running a neural network that has a target architecture.

The pre-evaluation criteria can also include one or more estimated performance criteria which rejects any candidate hardware architectures that have been preliminarily estimated to fall short of a satisfactory hardware performance on the particular machine learning task, e.g., in terms of the target runtime latency of a neural network configured to perform the particular machine learning task when deployed on the hardware accelerator, the target area of the hardware accelerator, or the target power consumption of the hardware accelerator when performing the task.

In particular, the system can determine the estimated hardware performance measures based on using any of a variety of techniques that constitute computationally inexpensive alternatives to the costly hardware simulators.

In some cases, the system can determine the estimated hardware performance measures based on comparing the selected values for the plurality of hardware parameters of the candidate hardware architecture with respective values of the plurality of hardware parameters of other known hardware architectures, the performance measures of which may have already been evaluated using the hardware simulators. The system then estimates, based on the comparison, whether the candidate hardware architecture may outperform (or underperform) the other known hardware architectures and, correspondingly, determine the estimated hardware performance measure of the candidate hardware architecture.

In other cases, the system can use machine learning-based techniques to determine the estimated accelerator performance measures. For example, the system can use a neural network, e.g., a feedforward neural network, that is configured to receive as input data that specifies the architecture of the hardware accelerator and to process the input in accordance with current values of the parameters of the neural network to generate as output a prediction for the area of the hardware accelerator. As another example, the system can use another neural network that is configured to receive as input data that specifies the architecture of the hardware accelerator and data that specifies the respective architecture of a target neural network, and to process the input in accordance with current values of the parameters of the neural network to generate a prediction for the latency of the target neural network in performing the task once deployed on the hardware accelerator. To ensure that the neural network can effectively estimate the performance measures, the neural network may be trained by using supervised training techniques on labelled training data generated by using the aforementioned hardware simulators. Once trained, the neural network can be used to effectively estimate the hardware performance measures, despite consuming significantly reduced amount of time, computational resources, or both than the costly hardware simulators.

In yet other cases, the system can maintain data, e.g., in the format of a look-up table, that specifies, for each possible hardware component that could be included in the candidate architecture, the corresponding size or the power consumption required to use the component to perform the task. The system can then determine the estimated area or power consumption of the candidate architecture by determining a sum of the size or power consumption values associated with the actual hardware components included in the candidate hardware accelerator architecture.

In response to a positive determination, the system proceeds to use the one or more hardware simulators to determine a performance measure of the candidate hardware architecture on the particular machine learning task (step 308). In particular, the system uses the hardware simulators to only evaluate the performance measures of the candidate hardware architectures that satisfy the pre-evaluation criteria, including those that have been determined to be feasible to build, and those that have been determined to have an acceptable estimated performance measure, e.g., an area (or latency) that is approximately equal to the target area (or latency) specified in the constraint data.

Depending on the specifics of the hardware design policy used by the system, the performance measure determined by using the hardware simulators may then be used to update the hardware design policy and to drive the hardware design policy to propose new candidate hardware architectures that more effectively support the operation of a deployed neural network in performing the task, better satisfies the hardware design constraints specified by the constraint data, or both.

On the other hand, in response to a negative determination, the system bypasses using the one or more hardware simulators to evaluate the performance measure of the candidate hardware architecture on the particular machine learning task. In some cases, the process 300 can directly return to step 302 to generate and evaluate another candidate architecture. In other cases, the system can treat the estimated performance measures as if they were determined by using the costly hardware simulators and use them to update the hardware design policy when appropriate. In yet other cases, the system can update the hardware design policy in a way that discourages the policy from proposing similar candidate architectures to the candidate architecture that fails to satisfy the pre-evaluation criteria in the next iteration. For example, the system can generate a large, negative reward for a policy that is being updated using reinforcement learning training techniques.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a data communication network.

In this specification, the term “database” is used broadly to refer to any collection of data: the data does not need to be structured in any particular way, or structured at all, and it can be stored on storage devices in one or more locations. Thus, for example, the index database can include multiple collections of data, each of which may be organized and accessed differently.

Similarly, in this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework, a Microsoft Cognitive Toolkit framework, an Apache Singa framework, or an Apache MXNet framework.

Embodiments of the subject matter described in this specification can be implemented in a computing system that includes a back end component, e.g., as a data server, or that includes a middleware component, e.g., an application server, or that includes a front end component, e.g., a client computer having a graphical user interface, a web browser, or an app through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

1. A method performed by one or more computers, the method comprising:
receiving data specifying a plurality of hardware parameters each associated with one or more values;
receiving data specifying one or more predetermined values for each of one or more of the plurality of hardware parameters;
generating a plurality of candidate hardware architectures that are specific to a particular machine learning task by repeatedly performing the following operations:
selecting, based on (i) a hardware design policy and (ii) the one or more predetermined parameter values for each of one or more of the plurality of hardware parameters, a respective value for each of the plurality of hardware parameters;
determining, from the selected values for the plurality of hardware parameters, a candidate hardware architecture;
determining whether the candidate hardware architecture satisfies pre-evaluation criteria, including (i) determining a feasibility of the candidate hardware architecture and (ii) determining an estimated performance measure of the candidate hardware architecture on the particular machine learning task; and
in response to a positive determination, evaluating, using one or more hardware performance simulators, a performance measure of the candidate hardware architecture on the particular machine learning task; and
generating a final hardware architecture based on the plurality of candidate hardware architectures and on the performance measures.

2. The method of claim 1, wherein the hardware design policy comprises a random policy which performs sampling from the plurality of hardware parameters each associated with one or more values with uniform randomness.

3. The method of claim 1, wherein the hardware design policy comprises a Bayesian optimization policy.

4. The method of claim 1, wherein the hardware design policy comprises a regularized evolutionary search policy.

5. The method of claim 1, wherein the hardware design policy comprises a model-based optimization policy.

6. The method of claim 1, wherein the hardware design policy comprises a population-based black-box optimization policy.

7. The method of claim 5, wherein the following operations further comprise:
updating the hardware design policy based on the performance measure of the candidate hardware architecture on the particular machine learning task.

8. The method claim 1, further comprising:
in response to a negative determination, bypassing using the one or more hardware performance simulators to evaluate the performance measure of the candidate hardware architecture on the particular machine learning task.

9. The method of claim 8, further comprising updating the hardware design policy based on the negative determination.

10. The method of claim 8, further comprising removing the candidate hardware architecture from the plurality of candidate hardware architectures based on which the final hardware architecture is to be generated.

11. The method of claim 1, wherein the particular machine learning task comprises one or more of an image classification, object detection, semantic segmentation, speech recognition, or optical character recognition task.

12. The method of claim 1, wherein the performance measure of the candidate hardware architecture on the particular machine learning task comprises one or more of, for a hardware accelerator having the candidate hardware architecture:
a runtime latency of a neural network configured to perform the particular machine learning task deployed on the hardware accelerator,
an area of the hardware accelerator, or
a power consumption of the hardware accelerator.

13. The method of claim 1, wherein determining the feasibility of the candidate hardware architecture comprises determining whether the selected values of the plurality of hardware parameters satisfy one or more hardware design constraints.

14. The method of claim 1, wherein determining the estimated performance measure of the candidate hardware architecture on the particular machine learning task comprises comparing the selected values for the plurality of hardware parameters of the candidate hardware architecture with respective values of the plurality of hardware parameters of other candidate hardware architectures the performance measures of which have already been evaluated using the one or more hardware performance simulators.

15. The method of claim 1, wherein the one or more hardware performance simulators comprise a cycle-accurate simulator or an analytical model.

16. The method of claim 1, wherein the one or more predetermined values for each of one or more of the plurality of hardware parameters are associated with one or more predetermined hardware architectures for different hardware accelerators.

17. The method of claim 1, wherein the plurality of hardware parameters include:
one or more compute parameters;
one or more memory parameters, and/or
one or more bandwidth parameters.

18. The method of claim 1, wherein the hardware parameters define the number of processing elements along a first a dimension of a hardware accelerator and/or along a second, orthogonal, direction of the hardware accelerator.

19. The method of claim 1, wherein receiving data specifying the one or more predetermined values for each of one or more of the plurality of hardware parameters comprises:
receiving data specifying a known hardware design policy; and
implementing and using the known hardware design policy to determine the one or more predetermined values for each of one or more of the plurality of hardware parameters.

20. (canceled)

21. A system comprising one or more computers and one or more storage devices storing instructions that when executed by the one or more computers cause the one or more computers to perform operations comprising:
receiving data specifying a plurality of hardware parameters each associated with one or more values;
receiving data specifying one or more predetermined values for each of one or more of the plurality of hardware parameters;
generating a plurality of candidate hardware architectures that are specific to a particular machine learning task by repeatedly performing the following operations:
selecting, based on (i) a hardware design policy and (ii) the one or more predetermined parameter values for each of one or more of the plurality of hardware parameters, a respective value for each of the plurality of hardware parameters;
determining, from the selected values for the plurality of hardware parameters, a candidate hardware architecture;
determining whether the candidate hardware architecture satisfies pre-evaluation criteria, including (i) determining a feasibility of the candidate hardware architecture and (ii) determining an estimated performance measure of the candidate hardware architecture on the particular machine learning task; and
in response to a positive determination, evaluating, using one or more hardware performance simulators, a performance measure of the candidate hardware architecture on the particular machine learning task; and
generating a final hardware architecture based on the plurality of candidate hardware architectures and on the performance measures.

22. One or more computer storage media storing instructions that when executed by one or more computers cause the one or more computers to perform operations comprising:
receiving data specifying a plurality of hardware parameters each associated with one or more values;
receiving data specifying one or more predetermined values for each of one or more of the plurality of hardware parameters;
generating a plurality of candidate hardware architectures that are specific to a particular machine learning task by repeatedly performing the following operations:
selecting, based on (i) a hardware design policy and (ii) the one or more predetermined parameter values for each of one or more of the plurality of hardware parameters, a respective value for each of the plurality of hardware parameters;
determining, from the selected values for the plurality of hardware parameters, a candidate hardware architecture;
determining whether the candidate hardware architecture satisfies pre-evaluation criteria, including (i) determining a feasibility of the candidate hardware architecture and (ii) determining an estimated performance measure of the candidate hardware architecture on the particular machine learning task; and
in response to a positive determination, evaluating, using one or more hardware performance simulators, a performance measure of the candidate hardware architecture on the particular machine learning task; and
generating a final hardware architecture based on the plurality of candidate hardware architectures and on the performance measures.
